(19) United States
(12) Patent Application Publication
(10) Pub. No.: US 2006/0156177 A1
(43) Pub. Date: Jul. 13, 2006

(54) Method and apparatus for recovering from soft errors in register files

(76) Inventors: Sailesh Kottapalli, San Jose, CA (US); Swati R. Nadkarni, Cupertino, CA (US); Tom E. Wang, Milpitas, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/026,360

(22) Filed: Dec. 29, 2004

(51) Int. Cl. H03M 13/00

(52) U.S. Cl. 714/758

(57) ABSTRACT

An apparatus and method for recovering from soft errors in register files is disclosed. In one embodiment, an apparatus includes a register file and error-correcting-code generation logic. Each register in the register file has bits to store data and bits to store an error-correcting-code value for the data.

### BACKGROUND

1. Field

The present disclosure pertains to the field of data processing apparatuses and, more specifically, to the field of error detection and correction in data processing apparatuses.

2. Description of Related Art

As improvements in integrated circuit manufacturing technologies continue to provide for smaller dimensions and lower operating voltages in microprocessors and other data processing apparatuses, makers and users of these devices are becoming increasingly concerned with the phenomenon of soft errors. Soft errors, as opposed to hard errors from design and manufacturing defects, arise when alpha particles and high-energy neutrons strike integrated circuits and alter the charges stored on the circuit nodes. If the charge alteration is sufficiently large, the voltage on a node may be changed from a level that represents one logic state to a level that represents a different logic state, in which case the information stored on that node becomes corrupted. Generally, soft error rates increase as circuit dimensions decrease, because the likelihood that a striking particle will hit a voltage node increases when circuit density increases. Likewise, as operating voltages decrease, the difference between the voltage levels that represent different logic states decreases, so less energy is needed to alter the logic states on circuit nodes and more soft errors arise.

Blocking the particles that cause soft errors is extremely difficult, so data processing apparatuses often include mechanisms for detecting, and sometimes correcting, soft errors. Typically, these mechanisms are focused on protecting memory elements such as system memory and caches through the use of hardware to generate and check parity bits and error-correcting-code (ECC) values that correspond to data stored in the memory elements. For example, automatic, in-line error correction may be accomplished by inserting hardware between the memory element and the execution unit of the data processor to generate a “syndrome” that indicates whether any single data bit has been corrupted, and to invert the value of any such corrupted bit. Alternatively, a memory element may automatically or periodically be “scrubbed” by checking for errors and rewriting the correct data into any memory locations that have become corrupted.

Less commonly, due to the relatively high cost of the additional circuitry required, redundant hardware schemes may be used to protect the execution core of data processing apparatuses from soft errors. A less costly, but less complete approach is to add parity bits to the register files in the execution core to provide for the detection of soft errors in the register files. However, the in-line error correction and scrubbing techniques discussed above are not typically used for register files because they would decrease performance or increase logic complexity, with in-line error correction by adding one or more stages to the execution pipeline between the register read and the execution stages, and with scrubbing by introducing replay loops into the critical path of the execution pipeline or by consuming otherwise useful clock cycles to perform the scrubbing. Therefore, data processing apparatuses generally cannot recover automatically from soft errors in register files, so the increasing size of register files results in more downtime and service calls, thereby decreasing the availability and increasing the cost of use of the equipment.

### BRIEF DESCRIPTION OF THE FIGURES

The present invention is illustrated by way of example and not limitation in the accompanying figures.

FIG. 1 illustrates a processor embodying techniques for recovering from soft errors in a register file.

FIG. 2 illustrates an ECC scheme according to an embodiment of the present invention.

FIG. 3 illustrates a register file according to an embodiment of the present invention.

FIG. 4 illustrates a system embodying techniques for recovering from soft errors in a register file.

FIG. 5 illustrates an embodiment of an execution pipeline in a processor embodying techniques for recovering from soft errors in a register file.

FIG. 6 illustrates an embodiment of a method for recovering from soft errors in a register file.

### DETAILED DESCRIPTION

The following description describes embodiments of techniques for recovering from soft errors in register files. In the following description, numerous specific details such as processor and system configurations, register arrangements, and ECC schemes, are set forth in order to provide a more thorough understanding of the present invention. It will be appreciated, however, by one skilled in the art that the invention may be practiced without such specific details. Additionally, some well known structures, circuits, and the like have not been shown in detail, to avoid unnecessarily obscuring the present invention.

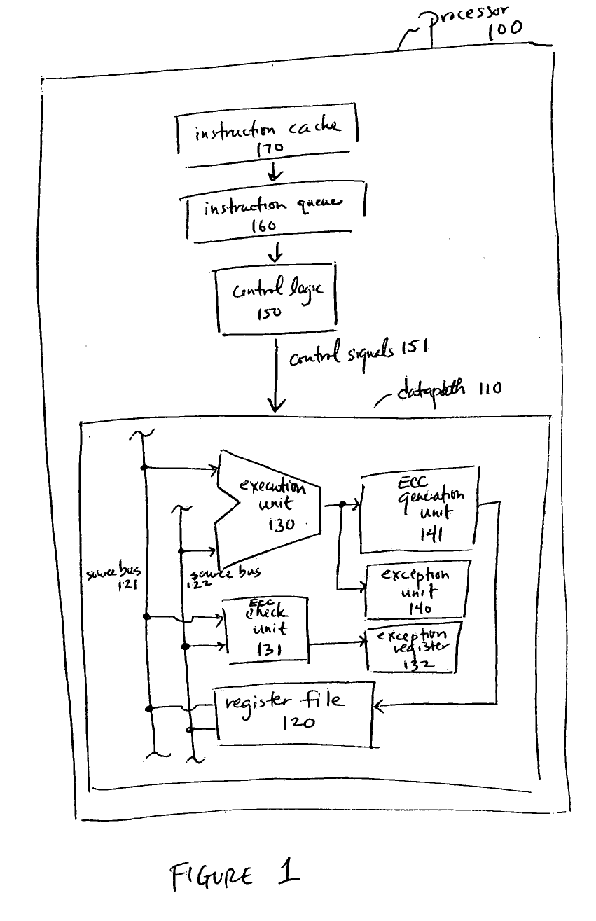

FIG. 1 illustrates a processor 100 embodying techniques for recovering from soft errors in a register file. The processor may be any of a variety of different types of processors that include register files. For example, the processor may be a general purpose processor such as a processor in the Pentium® Processor Family, the Itanium® Processor Family, or other processor family from Intel Corporation, or another processor from another company.

In the embodiment of FIG. 1, processor 100 includes datapath 110, having a register file 120, an execution unit 130, ECC check unit 131, exception register 132, exception unit 140, and ECC generation unit 141. Register file 120 includes a number of physical registers. A single physical register may correspond to or effectively serve as an architectural register in embodiments that do not utilize register renaming techniques. In embodiments utilizing register renaming techniques, different physical registers may hold the value of an architectural register at different points in time.

Execution unit 130 operates on data from source buses 121 and 122, in response to control signals 151. For example, execution unit 130 may be a shifter, an arithmetic logic unit, a floating point unit, a multimedia unit, or any unit or combination of units capable of performing any operation on data, where data may be any type of information, including instructions, represented by binary digits or in any other form. Processor 100 may include any number of execution units, each capable of performing any one or more operations on data. Control signals 151 are generated by control logic 150 to issue an instruction stored in instruction queue 160. Control logic 150 may be implemented with any well known technique, such as microcoding. Instruction queue 160 may be loaded with an instruction from instruction cache 170.

The result of the operation performed by execution unit 130 is checked for errors, such as arithmetic overflows, by exception unit 140. If an error is detected, the normal flow of instruction execution is modified before the result is committed to an architectural register.

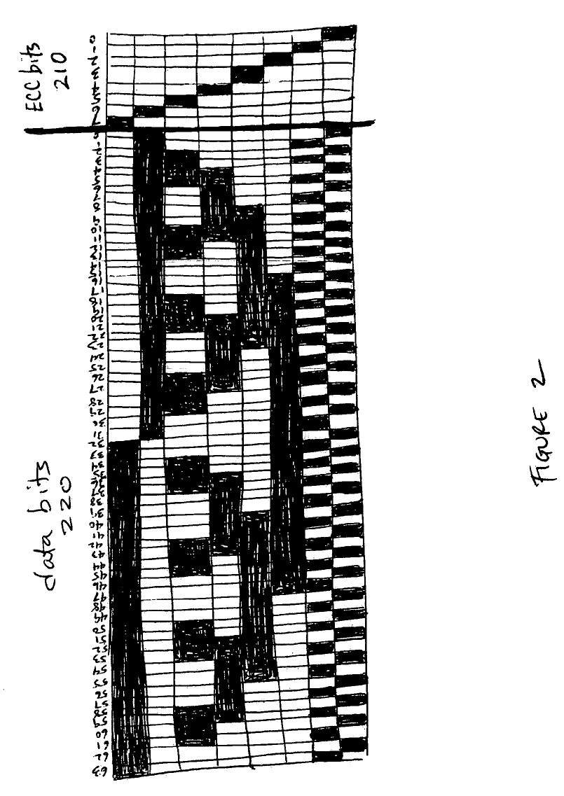

An ECC value corresponding to the result of the operation performed by execution unit 130 is generated, according to any well-known technique, by ECC generation unit 141. For example, where the result of the operation is a 64-bit data value represented by ones and zeroes, an 8-bit ECC value is generated according to the scheme illustrated in FIG. 2. In the scheme of FIG. 2, the value of each of ECC bits 210(0) to 210(7) is generated by calculating parity over a unique half of the data bits 220(0) to 220(63). For example, the value of ECC bit 210(7) is set to one if the number of ones in data bits 220(32) to 220(63) is odd.

ECC generation unit 141 may be implemented to generate an ECC value that may be used to detect an error in one or more bits of a corresponding data value, and to correct any subset of those errors. In the embodiment of FIG. 2, ECC bits 210(0) and 210(1) provide sufficient information to detect all single bit errors and adjacent double bit errors, and the full 8-bit ECC value provides sufficient information to identify the location of, and therefore correct, any single bit error, and to detect additional double bit errors. For example, if the 64-bit data value is “0000 0000 0000 0000 0000 0000 0000 0000 0000 0000 0000 0000 0000 0000 0000 0001,” an ECC value of “0100 0001” will be generated and stored. Assume that a single bit error causes the lowest data bit to change from a one to a zero. The ECC value for the corrupted data is “0000 0000,” which indicates that the value of the lowest data bit has changed.

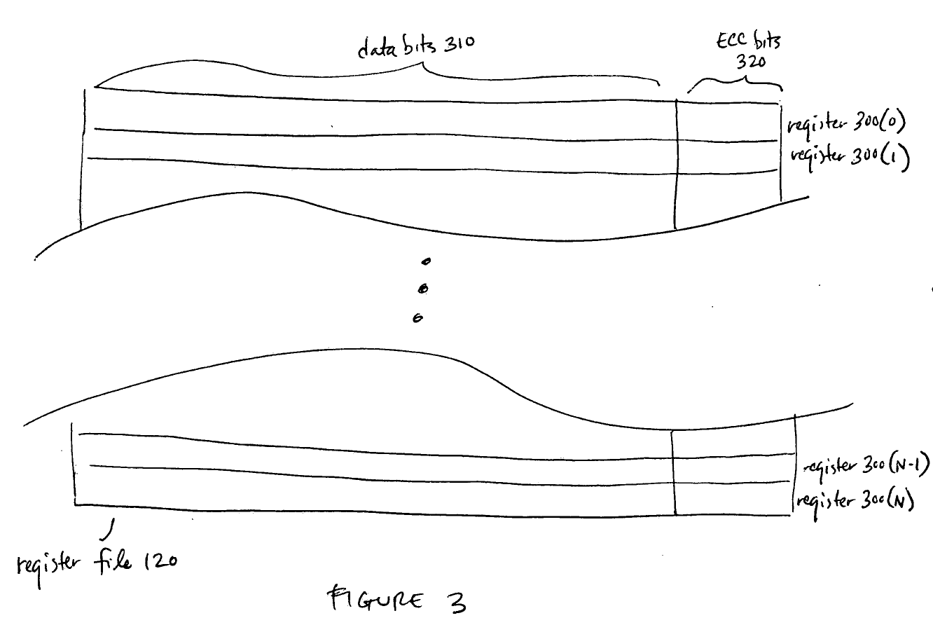

After the ECC value is generated, it is stored in register file 120 along with the corresponding data. FIG. 3 is a more detailed illustration of register file 120 according to an embodiment where the result of an operation is 64 bits wide. Register file 120 includes N registers 300(0) to 300(N), where N may be any integer. Each register 300 has data bits 310 to store a 64-bit data value and ECC bits 320 to store a corresponding 8-bit ECC value.

Data read from register file 120 is checked for parity errors by ECC check unit 131. For example, according to the ECC scheme of FIG. 2, each or any subset of 32 data bits along with its corresponding ECC bit may be checked to determine if the number of ones is even. Alternatively, a complete ECC value may be generated from the data read from the register, and compared to the ECC value read from the register. If it detects an error, ECC check unit 131 indicates that an error has been detected, by, for example, triggering a machine check exception (“MC”) in an embodiment using the well-known Machine Check Architecture (“MCA”) technology. In addition, ECC check unit 131 may store processor state information, such as an index identifying the register from which the data was read, in an exception register 132, such as a Machine Specific Register (“MSR”).

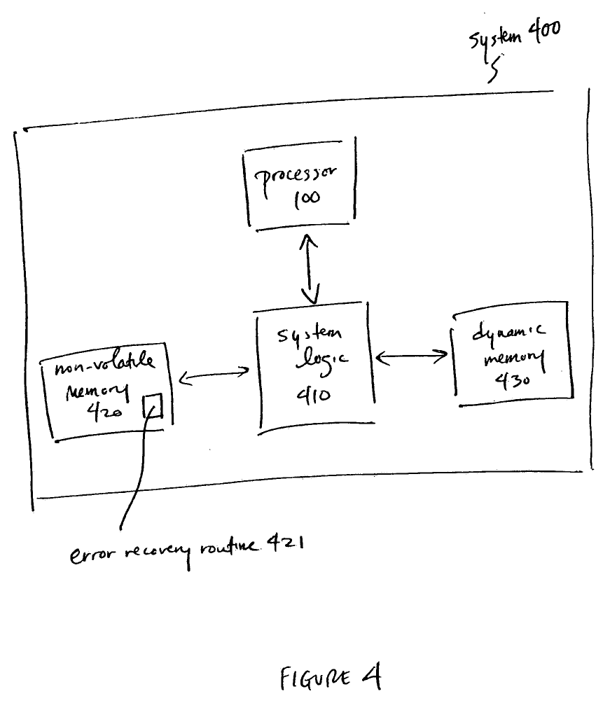

In an embodiment of the invention, the capability to detect an error in a register file is provided in hardware, as described above, and the capability to correct the error is provided in processor specific firmware. Offloading the error correction to firmware simplifies the hardware support requirements. For example, FIG. 4 illustrates a system 400 embodying techniques for recovering from soft errors in register files. In the embodiment of FIG. 4, processor 100 is connected to non-volatile memory 420, such as a read-only or flash memory, and dynamic memory 430, such as a dynamic random access memory, through system logic 410. An error recovery routine 421 is stored in non-volatile memory 420, and may be shadowed in dynamic memory 430. When an MC is triggered by ECC check unit 131, the flow of instruction execution is modified such that error recovery routine 421 is executed. Error recovery routine 421 may include instructions to automatically correct errors and cause processor 100 to resume executing the original sequence of instructions. In the event that an uncorrectable error occurs, for example, in the event of a double bit error in an embodiment using an ECC scheme that provides sufficient information to detect, but not to correct double bit errors, the error may be flagged and user intervention may be requested.

Together, FIGS. 1, 2, 3, and 4 may be used to illustrate an embodiment of the invention that automatically recovers from single bit soft errors in register files using MCA technology. For example, assume that the 64-bit result of an operation from execution unit 130 has been stored, along with its corresponding ECC value generated by ECC generation unit 140, in register 300(0), when an alpha particle strikes a node of register 300(0) and causes a single bit error in the data stored in register 300(0). Subsequently, an instruction using the data from register 300(0) is issued. The data from register 300(0) is read, and, when ECC check unit 131 detects the error, an index identifying the source register, register 300(0) in this case, is stored in an MSR, and an MC is triggered. The MC is handled by transferring instruction flow to error recovery routine 421. Error recovery routine 421 may include instructions to read the register index from the MSR and then re-read the data and the ECC value from the register identified by the register index. An ECC value generated from the corrupted data during the processing of the original instruction may be also be stored in and read from an MSR, or may be generated from the corrupted data re-read from the register under the control of error recovery routine 421. Error recovery routine 421 may include instructions to then compare the ECC value generated from the corrupted data to the original ECC value to identify which bit of data has been corrupted. Alternatively, the corrupted bit may be identified by calculating parity over each of the eight subsets of 32 data bits plus one parity bit, either during the initial processing of the original instruction or by error recovery routine 421, and using the combination of subsets failing the parity check to determine which bit has changed. Error recovery routine 421 may include instructions to then invert that bit, write the corrected data back to register 300(0), reload, into instruction queue 160, the instruction that tried to use the corrupted data, and cause processor 100 to resume execution of the original sequence of instructions.

Embodiments of the invention may include techniques to avoid nested error detection during the firmware correction process. For example, ECC check unit 131 may be disabled while error recovery routine 421 is being executed. Alternatively, the corrupted register state may be saved in an MSR, so that error recovery routine 421 would not need to include an instruction to re-read the corrupted data, and error checking could continue to be performed during the firmware correction process.

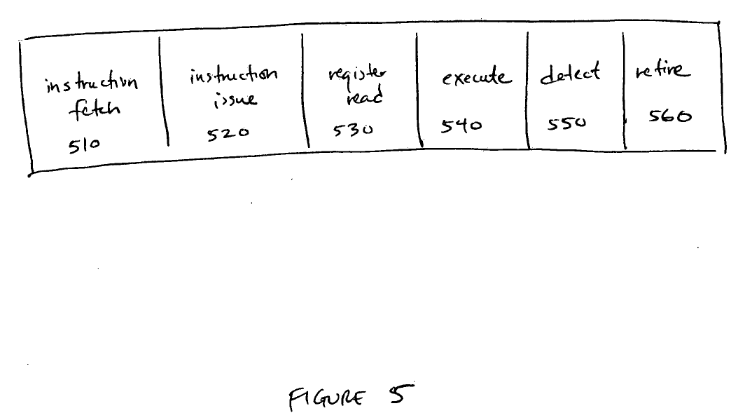

Although not required by the present invention, well-known pipelining techniques may be implemented in processor 100 to overlap the execution of multiple instructions. For example, FIG. 5 illustrates an embodiment of an execution pipeline 500 of processor 100. In instruction fetch stage 510, instruction queue 160 is loaded with an instruction from instruction cache 170. In instruction issue stage 520, control signals 151 are generated by control logic 150 to issue an instruction stored in instruction queue 160. In register read stage 530, data from register file 120 is latched onto source buses 121 and 122 to provide the operands for an instruction to be executed. In execution stage 540, execution unit 130 operates on the data from source buses 121 and 122 in response to control signals 151. In detect stage 550, exception unit 140 checks the result from execution unit 130 for errors. In retire stage 560, the result of an operation is written to register file 120. Each stage may represent a single clock cycle or any fraction or multiple of a single clock cycle, and any number of each of the described stages or any other stages may be used within the scope of the present invention.

ECC value checking and generation may be performed without altering the pipeline of FIG. 5. ECC check unit 131 may be connected to source buses 121 and 122 so as to perform parity checking on data from source buses 121 and 122 at the same time that execution unit 130 is operating on the data, e.g., in execution stage 540, or, alternatively, at any other time after the data is read from register file 120 and before the result of the operation is committed to an architectural register. ECC generation unit 141 may be connected to execution unit 130 and register file 120 so as to perform ECC value generation on the result of an operation at the same time that exception unit 140 is checking the result for errors, e.g., in detect stage 550, or, alternatively, at any time after the result is generated by execution unit 130 and before it is committed to an architectural register.

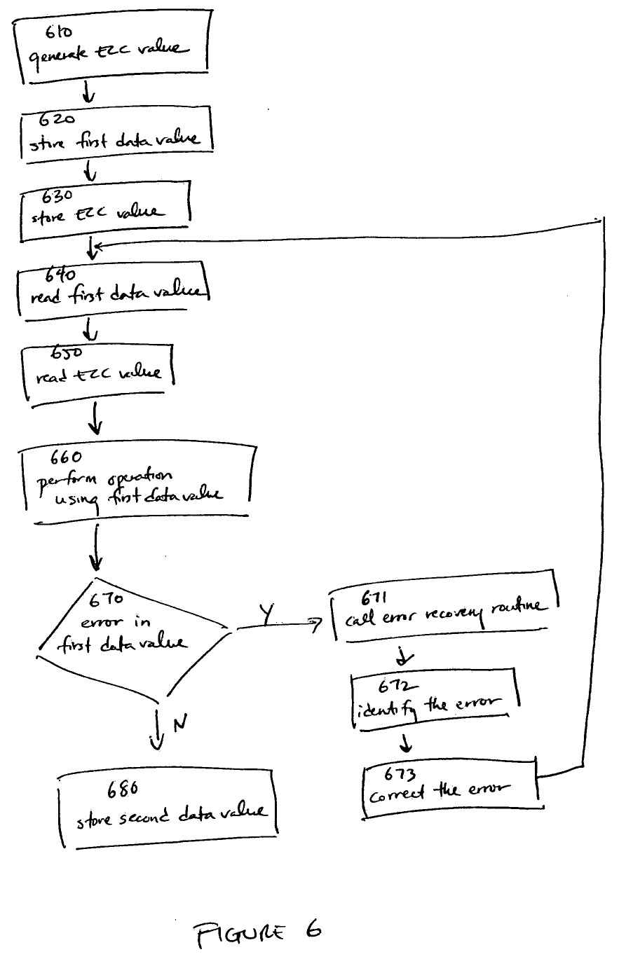

FIG. 6 is a flowchart illustrating an embodiment of a method for automatically recovering from single bit errors in register files. In block 610, an ECC value corresponding to a first data value is generated. In blocks 620 and 630, which may be performed in parallel, the first data value and the ECC value, respectively, are stored in a register file. In blocks 640 and 650, which may be performed in parallel, the first data value and the ECC value, respectively, are read from the register file. In block 660, an operation using the first data value is performed to generate a second data value. In block 670, the ECC value is used to check for errors in the first data value. Blocks 660 and 670 may be performed in parallel. If, in block 670, no errors are detected, then, in block 680, the second data value is stored in the register file. If, however, in block 670, an error is detected, in block 671 an index identifying the register from which the first data value was read is stored, and an error recovery routine is called. In block 672, the error recovery routine uses the ECC value to identify the error. In block 673, the error recovery routine corrects the error and stores the corrected data in the register from which the first data value was read, and the method returns to block 640.

Processor 100, or any other processor designed according to an embodiment of the present invention, may be designed in various stages, from creation to simulation to fabrication. Data representing a design may represent the design in a number of manners. First, as is useful in simulations, the hardware may be represented using a hardware description language or another functional description language. Additionally or alternatively, a circuit level model with logic and/or transistor gates may be produced at some stages of the design process. Furthermore, most designs, at some stage, reach a level where they may be modeled with data representing the physical placement of various devices. In the case where conventional semiconductor fabrication techniques are used, the data representing the device placement model may be the data specifying the presence or absence of various features on different mask layers for masks used to produce an integrated circuit.

In any representation of the design, the data may be stored in any form of a machine-readable medium. An optical or electrical wave modulated or otherwise generated to transmit such information, a memory, or a magnetic or optical storage medium, such as a disc, may be the machine-readable medium. Any of these mediums may “carry” or “indicate” the design, or other information used in an embodiment of the present invention, such as the instructions in an error recovery routine. When an electrical carrier wave indicating or carrying the information is transmitted, to the extent that copying, buffering, or re-transmission of the electrical signal is performed, a new copy is made. Thus, the actions of a communication provider or a network provider may be making copies of an article, e.g., a carrier wave, embodying techniques of the present invention.

Thus, techniques for recovering from soft errors in register files are disclosed. While certain embodiments have been described, and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art upon studying this disclosure. In an area of technology such as this, where growth is fast and further advancements are not easily foreseen, the disclosed embodiments may be readily modifiable in arrangement and detail as facilitated by enabling technological advancements without departing from the principles of the present disclosure or the scope of the accompanying claims.

What is claimed is:

1. An apparatus comprising:
a plurality of registers, each having a first number of bits to store data and a second number of bits to store one of a plurality of error-correcting-code values for the first number of bits; and
generation logic to generate the plurality of error-correcting-code values.

2. The apparatus of claim 1 wherein the error-correcting-code is a single-bit error-correcting-code.

3. The apparatus of claim 2 wherein:
the second number of bits is also to store one of a plurality of double-bit error-detecting-code values for the first number of bits; and
the generation logic is also to generate the plurality of double-bit error-detecting-code values.

4. The apparatus of claim 1 further comprising check logic to check the first number of bits and the second number of bits for an error.

5. The apparatus of claim 1 further comprising an execution unit to operate on the data and generate resulting data to store in one of the plurality of registers.

6. The apparatus of claim 5 further comprising check logic to check the first number of bits and the second number of bits for an error before the resulting data is stored in one of the plurality of registers.

7. The apparatus of claim 1 wherein the generation logic is to generate the one of the plurality of error-correcting-code values for data before the data is stored in one of the plurality of registers.

8. The apparatus of claim 4 wherein the check logic is also to respond to the detection of an error by triggering an exception.

9. The apparatus of claim 4 wherein the check logic is also to respond to the detection of an error by triggering an exception to transfer control of the apparatus to firmware to correct the error.

10. An apparatus comprising:
a processor having:
a plurality of registers, each register having a first number of bits to store data and a second number of bits to store one of a plurality of error-correcting-code values for the first number of bits;
generation logic to generate the plurality of error-correcting-code values before the first number of bits and the second number of bits is stored in one of the plurality of registers; and
check logic to check the first number of bits and the second number of bits for an error after the first number of bits and the second number of bits is read from the one of the plurality of registers, and to respond to the detection of an error by triggering an exception;
a non-volatile memory coupled to the processor to store instructions which, when executed by the processor in response to the triggering of the exception, cause the apparatus to correct the error and store the corrected data in the one of the plurality of registers; and
a dynamic random access memory coupled to the processor.

11. The apparatus of claim 10 further comprising an exception register to store an identifier of the one of the plurality of registers.

12. The apparatus of claim 11 wherein the non-volatile memory is also to store an instruction which, when executed by the processor in response to the triggering of the exception, causes the processor to re-read the first number of bits from the one of the plurality of registers.

13. The apparatus of claim 12 wherein the non-volatile memory is also to store an instruction which, when executed by the processor in response to the triggering of the exception, disables the check logic before the processor re-reads the first number of bits from the one of the plurality of registers.

14. The apparatus of claim 10 further comprising an exception register to store the first number of bits read from the one of the plurality of registers.

15. A method comprising:
performing a first operation to generate a first data value;
before storing the first data value, generating an error-correcting-code value corresponding to the first data value; and
storing the first data value and the error-correcting-code value in a register.

16. The method of claim 15 further comprising:
reading the first data value and the error-correcting-code value from the register;
performing a second operation to generate a second data value using the first data value;
using the error-correcting-code value to check the first data value; and
before storing the second data value, triggering an exception to indicate the presence of an error in the first result.

17. The method of claim 16 further comprising:
calling an error recovery routine to generate a corrected first data value using the error-correcting-code value; and
storing the corrected first data value in the register.
